(19) United States
(12) Patent Application Publication
(10) Pub. No.: US 2009/0085436 A1
(43) Pub. Date: Apr. 2, 2009

(54) Electrical Component that Includes a Ceramic Substrate and Piezoelectric Transformer

(76) Inventors: Igor Kartashev, Deutschlandsberg (AT); Guenter Pudmich, Koeflach (AT)

Correspondence Address: SLATER & MATSIL, L.L.P., 17950 PRESTON RD, SUITE 1000, DALLAS, TX, 75252-5793, US

(21) Appl. No.: 12/245,162

(22) Filed: Oct. 3, 2008

Related U.S. Application Data
(63) Continuation of application No. PCT/DE2007/000622, filed on Apr. 5, 2007.

(30) Foreign Application Priority Data
Apr. 5, 2006 (DE) 10 2006 015 980.2

(51) Int. Cl. H01L 41/107; H01L 41/053

(52) U.S. Cl. 310/318; 310/352; 310/326

(57) ABSTRACT

An electrical component includes a ceramic substrate and a piezoelectric transformer, which is connected electrically and mechanically to the ceramic substrate.

This application is a continuation of co-pending International Application No. PCT/DE2007/000622, filed Apr. 5, 2007, which designated the United States and was not published in English, and which claims priority to German Application No. 10 2006 015 980.2 filed Apr. 5, 2006, both of which applications are incorporated herein by reference.

### BACKGROUND

From publication US 2001/0028206 A1, a piezoelectric transformer is known, in which internal electrodes are provided in the interior of a body.

### SUMMARY

One task to be achieved is to specify an electrical component with a piezoelectric transformer that exhibits low losses.

Embodiments of the invention specify an electrical component that includes a ceramic substrate, which has contact surfaces, and a piezoelectric transformer, which is connected electrically to at least a few of the contact surfaces of the substrate and which is arranged at least partially on the ceramic substrate.

In the following, advantageous embodiments of the specified component will be described.

The piezoelectric transformer comprises a body. The transformer body comprises an input part, an output part, and an insulation region arranged between these parts, wherein, in one advantageous embodiment, this region is formed by a region of the ceramic substrate.

The region provided as an insulation region of the piezoelectric transformer advantageously has a thinner construction than other regions of the ceramic substrate. In this way it is possible to form a component with an especially small overall height.

The component comprises electrical feed lines for contacting the piezoelectric transformer, wherein these lines are advantageously integrated at least partially in the ceramic substrate. The electrical feed lines comprise at least one electrical connection running vertical to the substrate surface.

The component can comprise at least one electrical circuit that is connected electrically to the piezoelectric transformer and that is at least partially integrated in the ceramic substrate. This circuit can be suitable, in particular, for signal or data processing.

The component can comprise at least one electrical component, which is connected electrically to the piezoelectric transformer and which is arranged on the ceramic substrate. This component is advantageously constructed as a chip. This component can comprise at least one capacitor, at least one inductor, or a chip suitable for signal or data processing.

The ceramic substrate can have at least one recess for holding at least one of the transformer parts. Each transformer part can be countersunk in such a recess. The ceramic substrate may at least partially house at least one part of the piezoelectric transformer.

The piezoelectric transformer can comprise a body whose surface has at least one node region, in which nodes appear of an acoustic wave stimulated in the body. The body is advantageously connected in the node regions to the ceramic substrate and is spaced apart from this substrate in the other regions.

A node region extends on the base surface of the body along a line, which runs perpendicular to the direction of wave propagation. The node region advantageously extends in a width direction of the transformer body. For operation of the transformer in the fundamental mode, i.e., the first harmonic of an acoustic wave, only one node region is provided approximately in the middle of the body. For the operation of the transformer at the second harmonic, two node regions are present, which are in the middle of the body spaced apart from the end faces by approximately one-quarter wavelength.

The electrical contacts of the transformer parts can be connected to the contact surfaces of the ceramic substrate by means of wires. The electrical contacts of the transformer parts and those of the ceramic substrate can also lie opposite each other and can be connected to each other by a solder connection.

The component can also comprise a carrier substrate, on which the ceramic substrate is mounted with the piezoelectric transformer, wherein electrical feed lines for connecting the ceramic substrate to an electrical circuit realized in or on the carrier substrate are integrated in the carrier substrate.

In one embodiment, the body contacts, in the region of its base surface, the ceramic substrate, wherein at least 90% of the base surface of the body is mechanically decoupled from the ceramic substrate.

There can be at least two coupling regions, which are spaced apart from each other and in which the transformer body is connected rigidly to the ceramic substrate. They are advantageously arranged in a node region along a node line. As a node line, a line is designated, at which the deflection amplitude of the body is zero. Advantageously, for each node region there are two coupling regions.

In particular, for the operation at the first harmonic, it is advantageous to arrange at least two contact regions, which are spaced apart from each other, which are mounted on the ceramic substrate and which contact the body, next to two coupling regions arranged in the node region. The contact regions advantageously have vibration-damping properties.

The contact regions are advantageously arranged along the direction of wave propagation, e.g., along the longitudinal axis of the body. The coupling regions are advantageously arranged along a line that runs perpendicular to the direction of wave propagation and to the longitudinal axis of the body.

### BRIEF DESCRIPTION OF DRAWINGS

Below, advantageous embodiments will be explained with reference to schematic figures that are not true to scale. Shown are:

FIG. 1, shows an electrical component with a ceramic substrate and an integrated piezoelectric transformer;

FIG. 2A, shows an electrical component with a ceramic substrate and a piezoelectric transformer arranged on this substrate in a side view;

FIG. 2B, shows the electrical component according to FIG. 2A in cross section;

FIG. 3, shows a modular component, in which a component according to FIG. 1 is integrated;

FIG. 4, shows a top view of the base surface (bottom side) of a transformer operated at the second harmonic; and

FIG. 5, shows a top view of the base surface (bottom side) of a transformer operated at the first harmonic.

The following reference symbols can be used in conjunction with the drawings:
1 Ceramic substrate
2 Region of the ceramic substrate in which the piezoelectric transformer is arranged
3 Piezoelectric transformer
30 Region of the substrate 1 with lower thickness
4 Primary part of the transformer
41, 42 Electrodes of the primary part
43, 44 Contact surfaces of the ceramic substrate
45 Bonding wire
46, 46′ Feed line
5 Secondary part of the transformer
51, 52 Electrodes of the secondary part
53, 54, 56 Contact surfaces of the ceramic substrate
55 Bonding wire
57, 59 Via contacts
58, 58′ Feed line
6, 7 Node regions
61, 62 Contact surfaces of the carrier 13
63, 64 Contact surfaces of the carrier 13
8, 9 Contact regions
10 Insulation region
11 Recess
12 Electrical component, comprising piezoelectric transformer and ceramic substrate
13 Carrier
14 Opening
P Polarization

### DETAILED DESCRIPTION

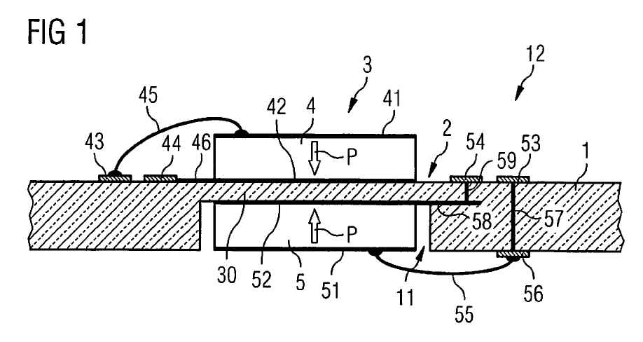

FIG. 1 shows an electrical component 12 with a ceramic substrate 1 and a piezoelectric transformer 3, which is arranged in the region 2 of the ceramic substrate 1. The piezoelectric transformer 3 comprises a primary part 4 with the electrodes 41, 42 and a secondary part 5 with the electrodes 51, 52.

When an electrical voltage is applied to the electrodes 41, 42 of the primary part 4, mechanical stress, for a periodic signal, an acoustic wave, is generated, which is transmitted to the secondary part 5. An output voltage of the transformer can be tapped at the electrodes 51, 52 of the secondary part 5. The polarization direction between the electrodes of each transformer part is characterized with an arrow P.

The transformer 3 is advantageously a component of a power-supply part for supplying current or voltage to an electrical component or circuit, which is advantageously arranged on the substrate 1 or integrated in this substrate.

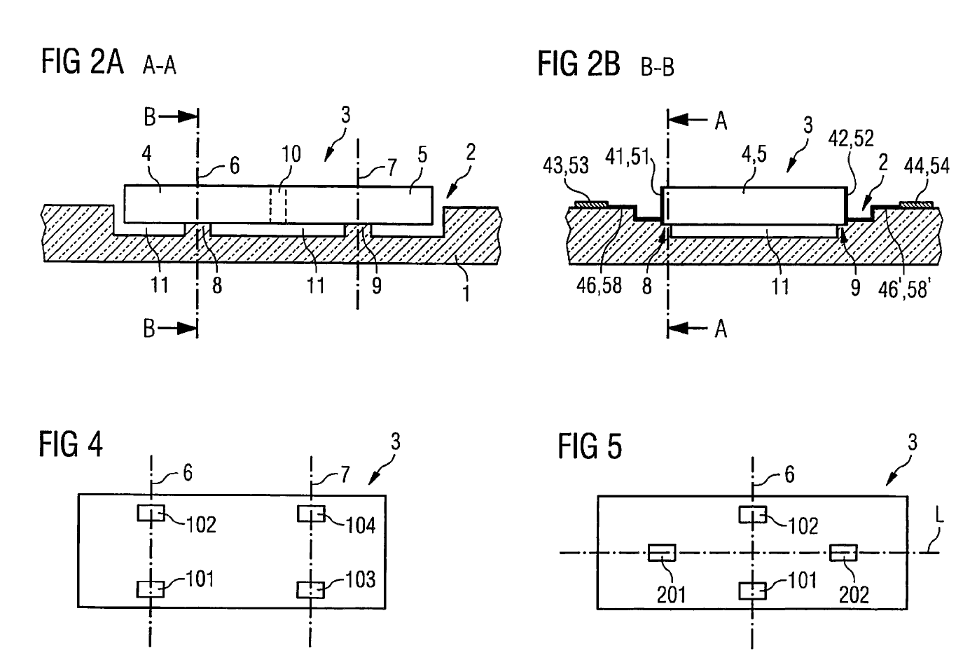

The transformer body is advantageously made from a ceramic-containing material. The electrodes 41, 42, 51, 52 are arranged in the embodiment according to FIG. 1 parallel to the main surfaces of the substrate 1. However, they can also run perpendicular to these surfaces, as in the embodiment presented in FIGS. 2A, 2B. An arrangement not shown in FIG. 1 of internal electrodes, which are arranged in the transformer body, can be connected to each electrode 41, 42, 51, 52. The internal electrodes are advantageously oriented parallel to the main surfaces of the substrate 1, so that the acoustic wave is stimulated in the vertical direction. The connection sequence of the internal electrodes is explained below.

Contact surfaces 43, 44, 53, 54 are arranged on the top side of the ceramic substrate 1 and a contact surface 56 is arranged on the bottom side. The first electrode 41 of the primary part 4 is connected to the contact surface 43 by means of a bonding wire 45. The second electrode 42 of the primary part 4 turned toward the substrate is connected to the contact surface 44 by means of a feed line 46 arranged on the top side of the substrate 1. This feed line connects the contact surface 44 and a contact surface of the substrate 1 soldered to the electrode 42.

The first electrode 51 of the secondary part 5 is connected to the contact surface 56 by means of a bonding wire 55. The contact surface 56 is connected electrically to the contact surface 53 by means of a via contact 57. The second electrode 52 of the secondary part 5 turned toward the substrate is connected to the contact surface 54 by means of a feed line 58 partially exposed and partially buried in the substrate 1 and a via contact 59. This feed line connects the contact surface 54 and a contact surface of the substrate 1 soldered to the electrode 52.

The contact surfaces 43, 44, 53, and 54 are provided as external electrodes of the component shown in FIG. 1. They all contact a main surface of the substrate 1. However, it is also possible to arrange the external electrodes of the component on both main surfaces of the substrate, i.e., both on the top side and also on the bottom side.

The contact surfaces 43, 44, and 53, 54 are arranged on opposite main surfaces of the substrate 1 and advantageously as far apart from each other as possible. A large distance between the contact surfaces, which are connected to the primary part and the secondary part, increases the breakdown strength of the specified component. The arrangement of all of the contact surfaces 43, 44 and 53, 54 on the same main surface of the substrate 1 is also possible.

The arrangement of the transformer 3 between the contact surfaces 43, 44 for the primary part 4 and the contact surfaces 53, 54 for the secondary part 5 is especially advantageous, because good electromagnetic decoupling of the transformer parts is thus possible. Here it is advantageous if the bonding wires 45, 55 are led out toward different main sides of the substrate 1 for contacting the various transformer parts. However, the arrangement of contact surfaces of the substrate, feed lines, and bonding wires can be, in principle, arbitrary. For example, it is possible for the contact surface 43 contacted by the bonding wire 45 to be connected electrically, e.g., via a feed line, to another contact surface provided as an external electrode for contacting the first electrode 41 of the primary part.

The substrate 1 has a transformer region 2, which is mechanically coupled to the transformer parts 4, 5. In the transformer region 2 there is a recess 11 for holding a transformer part, in FIG. 1 the secondary part 5. In the region 2 of the substrate, another recess could be provided for holding the other transformer part.

The transformer region 2 has a sub-region 30, which is a component of the transformer 3. Thus, the substrate 1 and the transformer 3 are integrated one in the other and cannot separate from each other, so that the electrical function of the transformer for signal transmission is fulfilled. Other regions of the substrate can be provided for integration of an electrical circuit or as a carrier for an electrical component.

The substrate regions differing from the transformer region 2 are advantageously thicker than the sub-region 30. Due to the jump in thickness at the boundary of the mentioned substrate regions, the acoustic impedances of these regions are different from each other. Thus, the acoustic wave stimulated in the thinner transformer region 2 is reflected back at the boundary to the remaining thicker region. Thus it is possible to localize the mechanical energy of the acoustic wave for the most part in the transformer region 2.

The sub-region 30 of the substrate 1, which has a smaller thickness than the other substrate regions, is provided as an insulation region of the transformer 3, which is arranged between the primary part 4 and the secondary part 5. This region creates a mechanical connection between the transformer parts 4, 5. This region can be, in principle, arbitrarily thin. A thin insulation region increases the efficiency of the piezoelectric transformer relative to a transformer with a thicker insulation region. Therefore, because the thickness of the substrate 1 in the sub-region 30 is significantly smaller than, e.g., in the substrate regions provided for attaching to an external carrier or as a carrier for additional electrical components, the mechanical coupling of the transformer 3 with the thick-walled remainder of the substrate is relatively small, so that the transformer 3 is essentially mechanically decoupled from the thicker regions of the substrate.

In the piezoelectric transformer 3 according to FIG. 1, acoustic oscillations are stimulated in the vertical direction, i.e., perpendicular to the main surface of the ceramic substrate 1. In contrast, in the piezoelectric transformer 3 according to FIGS. 2A, 2B, acoustic oscillations are stimulated in the longitudinal direction, i.e., parallel to the main surface of the ceramic substrate 1.

In FIGS. 2A and 2B, various cross sections A-A and B-B of another component are shown with a ceramic substrate 1 and a piezoelectric transformer 3 attached to this substrate. The body of the transformer comprises an insulation region 10, which is arranged between the transformer parts 4, 5. The body is block-shaped and is advantageously constructed as a ceramic plate with a rectangular cross section. The transformer 3 shown in FIGS. 2A, 2B is advantageously operated at the second harmonic of a longitudinal acoustic fundamental mode, wherein there are two node regions 6, 7 in the transformer body in the direction of wave propagation, which agrees with the longitudinal direction of the body. The electrical and mechanical coupling between the substrate 1 and the transformer body is advantageously essentially limited in these regions, which is why acoustic losses can be kept especially low by the mechanical coupling between the substrate 1 and the transformer 3. The electrode surfaces 41, 42, 51, 52 of the transformer 3 can extend past these regions.

In this embodiment, in region 2 of the substrate 1 there is a recess 11 for holding the entire transformer body. The acoustic wave propagates in the longitudinal direction of the body. The minimum of the acoustic standing wave and thus the minimum deflection of the body occurs in the node regions 6, 7. Therefore, the mechanical coupling between the base surface of the transformer body and the substrate 1 is essentially limited to the node regions 6, 7. This mechanical coupling is advantageously realized in two contact regions 8, 9, which each have a relatively small surface area. In FIG. 2B it is to be seen that a large middle region of the transformer body is mechanically decoupled from the ceramic substrate 1. This coupling is only limited to the corner or edge regions of the body. The surface of the coupling regions advantageously equals less than 10% of the base surface of the transformer body.

The contact regions 8, 9 are each formed by a step of a side wall of the recess 11. The contact regions 8, 9 can alternatively be constructed as projections arranged in the recess 11, wherein advantageously two projections are provided for each transformer part, that is, as a whole four projections. The height of such projections is advantageously smaller than the maximum depth of the recess 11.

The electrodes 41, 42 of the input part 4 are arranged on opposing side surfaces of the transformer body. The electrodes 51, 52 of the output part 5 are also arranged on these side surfaces, but at a distance from the electrodes 41, 42 of the input part 4.

The contact surfaces 43, 44 provided as external electrodes are connected conductively to the electrodes 41, 42 of the input part 4 via the feed lines 46 and 46′. The contact surfaces 53, 54 provided as external electrodes are connected conductively to the electrodes 51, 52 of the output part 5 via the feed lines 58 and 58′. Each electrode 41, 42, 51, 52 is advantageously soldered to the allocated feed line 46, 58, 46′, and 58′.

Each electrode 41, 42, 51, 52 is advantageously connected to an arrangement of internal electrodes that are arranged in the body of the transformer and that are not shown in the FIGS. 2A and 2B. Each arrangement of internal electrodes connected conductively to each other is advantageously connected only to one of the electrodes 41, 42, 51, 52 and is electrically insulated from the other electrodes. The internal electrodes are advantageously arranged perpendicular to the particular electrode of the transformer part to which they are connected. The internal electrodes, which are connected to the first and the second electrode of each transformer part, are advantageously arranged in an alternating configuration, i.e., they interlock with each other.

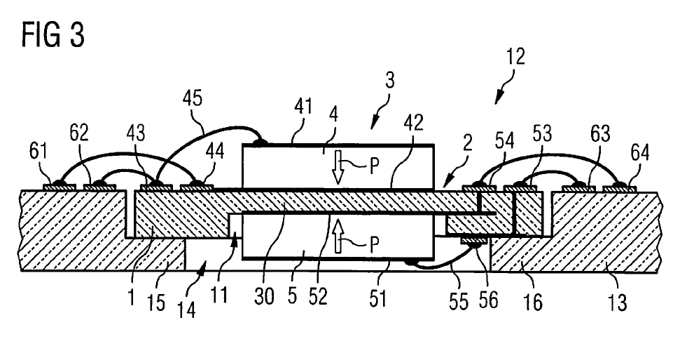

In FIG. 3, a component is shown with a carrier 13 in the form of a carrier plate, which can be, e.g., a printed circuit board or another ceramic substrate. This component comprises an electrical component 12, which is essentially constructed like the component explained in FIG. 1. In contrast to FIG. 1, the output part 5 of the transformer 3 is not countersunk in the recess 11, but instead projects downward and out of this recess.

In the carrier 13 there is an opening 14 or a recess for holding the component 12. At least two opposing side surfaces of this opening or recess each have advantageously one step 15, 16, which is formed as a contact surface for the substrate 1 of the component 12. The height of the step 15, 16 is selected so that the output part 5 of the transformer 3 is completely countersunk in the opening 14 and does not project from the carrier 13. The upper surface of the ceramic substrate 1 is arranged at the same height as the upper surface of the carrier 13, but can also lie lower or higher.

On the top side of the carrier 13 are contact surfaces 61, 62, 63, 64. The contact surface 61 of the carrier 13 is connected to the contact surface 44 of the ceramic substrate 1, the contact surface 62 is connected to the contact surface 43, the contact surface 63 is connected to the contact surface 53, and the contact surface 64 is connected to the contact surface 54 by means of bonding wires. Instead of bonding wires, electrical feed lines can otherwise also be considered.

On the region of the carrier 13 outside the opening 14, another electrical component can be mounted, which is connected electrically to the transformer 3 and which is advantageously supplied with voltage by this transformer. In the carrier 13, another circuit can also be integrated, which is connected electrically to the transformer 3 and which is advantageously supplied with voltage by this transformer.

In FIG. 4, an example arrangement of coupling regions for a transformer 3 operated at the second harmonic is shown. The transformer body is connected rigidly to the ceramic substrate 1 in four coupling regions 101, 102, 103, 104 spaced apart from each other. Two coupling regions 101, 102 are arranged at a distance from each other in the first node region 6 and two other coupling regions 103, 104 are arranged at a distance from each other in the second node region 7.

In FIG. 5, an example arrangement of coupling regions for a piezoelectric transformer operated at the first harmonic is shown. The transformer body is connected rigidly to the ceramic substrate 1 in two coupling regions 101, 102 that are spaced apart from each other. In addition, there are two contact regions 201, 202, which are spaced apart from each other, which are mounted on the ceramic substrate 1 and which contact the body. The contact regions 201, 202 are arranged along the direction of wave propagation and the longitudinal axis L of the transformer body. The contact regions can be made from, e.g., a relatively hard rubber.

The position of the coupling regions and the contact regions can differ from the examples shown in FIGS. 4 and 5. The contact regions can be arranged, in principle, in the end edge regions of the base surface.

The specified component is not limited to the examples shown in FIGS. 1 to 3 in terms of the geometric shape of the shown elements and also in terms of the type of mechanical coupling between the ceramic substrate and the transformer body. The transformer can have, in principle, an arbitrary construction.

What is claimed is:

1. An electrical component, comprising
a ceramic substrate; and
a piezoelectric transformer electrically and mechanically connected to the ceramic substrate.

2. The electrical component according to claim 1, wherein the piezoelectric transformer comprises an input part, an output part, and an insulation region arranged between the input and output parts, and wherein the insulation region is formed by a region of the ceramic substrate.

3. The electrical component according to claim 2, wherein the insulation region has a thinner construction than other regions of the ceramic substrate.

4. The electrical component according to claim 1, further comprising electrical feed lines for contacting the piezoelectric transformer, the feed lines being integrated at least partially in the ceramic substrate.

5. The electrical component according to claim 4, wherein the electrical feed lines comprise at least one via contact.

6. The electrical component according to claim 1, further comprising at least one electrical circuit that is electrically connected to the piezoelectric transformer and is integrated at least partially in the ceramic substrate.

7. The electrical component according to claim 1, further comprising at least one electrical component, that is electrically connected to the piezoelectric transformer and is arranged on the ceramic substrate.

8. The electrical component according to claim 1, wherein the ceramic substrate comprises at least one recess for holding at least one part of the piezoelectric transformer.

9. The electrical component according to claim 1, wherein the ceramic substrate at least partially houses at least one part of the piezoelectric transformer.

10. The electrical component according to claim 1,
wherein the piezoelectric transformer comprises a body, whose surface has one or more node regions, wherein nodes of an acoustic wave appear in the one or more node regions,
wherein the body is connected rigidly to the ceramic substrate only in the one or more node regions such that the body is spaced apart from the ceramic substrate in other regions.

11. The electrical component according to claim 1, further comprising a carrier substrate, the ceramic substrate being mounted on the carrier substrate with the piezoelectric transformer.

12. The electrical component according to claim 11, further comprising electrical feed lines integrated in the carrier substrate for connecting the ceramic substrate to an electrical circuit formed in or on the carrier substrate.

13. The electrical component according to claim 10, wherein the body is connected rigidly to the ceramic substrate at at least two coupling regions that are spaced apart from each other.

14. The electrical component according to claim 13, wherein the at least two coupling regions are arranged in the one or more node regions.

15. The electrical component according to claim 10,
further comprising at least two contact regions, that are spaced apart from each other and are mounted on the ceramic substrate and contact the body, wherein the contact regions have vibration-damping properties.
